(19) United States
(12) Patent Application Publication
(10) Pub. No.: US 2009/0180509 A1
(43) Pub. Date: Jul. 16, 2009

(54) Surface emitting semiconductor laser and method of manufacturing the same

(75) Inventors: Tomofumi Kise, Tokyo (JP); Noriyuki Yokouchi, Tokyo (JP)

Correspondence Address: KUBOTERA & ASSOCIATES, LLC, 200 Daingerfield Road, Suite 202, Alexandria, VA, 22314, US

(73) Assignee: The Furukawa Electric Co., Ltd.

(21) Appl. No.: 12/318,780

(22) Filed: Jan. 8, 2009

(30) Foreign Application Priority Data
Jan. 11, 2008 (JP) 2008-004410

(51) Int. Cl. H01S 5/18; H01L 21/02

(52) U.S. Cl. 372/50.124; 438/29; 257/E21.002

(57) ABSTRACT

A surface emitting semiconductor laser comprises a semiconductor substrate; a lamination structure including a lower multilayer film reflecting mirror, an active layer, and an upper multilayer film reflecting mirror formed on the semiconductor substrate; and an upper electrode and a lower electrode for supplying an electric power to the active layer. The upper multilayer film reflecting mirror has a refractive index having a two-dimensional periodic distribution within a lamination plane except a predetermined region in the lamination plane. A circular hole layer is formed above the active layer, and includes a plurality of circular holes arranged in a peripheral region surrounding the predetermined region in a two-dimensional periodic pattern, so that a multilayer film formed on the circular hole layer including an inside of the circular holes to constitute the upper multilayer film reflecting mirror forms the two-dimensional periodic distribution of the refractive index together with the circular hole layer.

### CROSS-REFERENCE TO RELATED APPLICATIONS

This application claims priority from a Japanese patent application No. 2008-4410 filed on Jan. 11, 2008, the entire content of which is incorporated herein by reference.

### BACKGROUND OF THE INVENTION

The present invention relates to a surface emitting semiconductor laser and a method of manufacturing the same. More specifically, the present invention relates to a surface emitting semiconductor laser capable of fundamental transverse mode oscillation and a method of manufacturing the same.

In a vertical cavity surface emitting semiconductor laser (VCSEL; referred to simply as “a surface emitting laser” hereinafter), a resonating direction of light is perpendicular to a substrate surface, as the term indicates. The surface emitting laser has attracted a significant amount of attention as a light source for communication including optical interconnection, or a variety of devices in a sensor application. The attention described above has been based on the following advantages. As opposed to a conventional edge emitting laser, in the surface emitting laser, elements are easily arranged in a two-dimensional arrangement. It is not necessary to provide a cleavage for installing a mirror, so that a wafer-level test is possible. Further, an active layer has an extremely small volume. Accordingly, it is possible to oscillate the surface emitting laser at an extremely low threshold, thereby reducing power consumption.

Especially, the surface emitting laser has an extremely small cavity length. It is possible to easily achieve fundamental mode oscillation in terms of a longitudinal mode of oscillation. On the other hand, the surface emitting laser does not have a control mechanism of transverse mode. Accordingly, the surface emitting laser tends to generate a plurality of higher order modes in terms of the transverse mode. When a laser oscillated with higher order transverse mode is used for optical transmission, a signal thereof is susceptible to degradation proportional to a transmission distance, especially under high-speed modulation. Thus, in the surface emitting laser, a variety of structures have been proposed as a measure for facilitating the fundamental transverse mode oscillation.

In order to obtain the fundamental transverse mode oscillation in a simple manner, an area of an active region is reduced to an extent that only the fundamental mode can oscillate. For example, when the surface emitting laser is an selective oxidation optical confined surface emitting laser having an selectively oxidized AlAs layer and an oscillation wavelength within an 850 nm band, a refractive index difference between a non-oxidized AlAs region and an oxidized region (Al₂O₃) becomes large. Accordingly, it is necessary to reduce an area of an active region not larger than about 10 μm² in order to achieve the fundamental transverse mode oscillation.

In the surface emitting laser having an oxidation constriction structure, a current constriction width, which controls an area of an active region, is determined by an oxidized layer formed through selectively oxidizing a peripheral region of the AlAs layer. In order to form an aperture such that the area of the active layer becomes not larger than about 10 μm² through forming the oxidized layer, it is necessary to precisely control the oxidation process, thereby lowering a product yield. In addition, when the area of the active region is reduced, not only an output thereof is lowered but also a device resistance increases, thereby increasing a voltage applied to the surface emitting laser.

In the surface emitting laser, in order to increase the area of the active region and achieve the fundamental transverse mode oscillation, for example, “IEEE Journal of Selected Topics in Quantum Electronics”, Vol. 9, No. 5, pp. 1439-1445, September/October 2003, has proposed a structure shown in FIG. 11. FIG. 11 is a cross sectional view schematically showing the surface emitting laser.

The surface emitting laser has an n-type GaAs substrate 1; a lamination structure constituted by a lower multilayer film reflecting mirror 2, an n-type clad layer 3, a quantum well active layer 4, a p-type clad layer 6, an oxidized constriction layer 5 in which a peripheral region is oxidized to form a current blocking region 5b and a current aperture 5a is formed in a central region, an upper multilayer film reflecting mirror 9 in which a plurality of circular holes 7 are arranged in a two-dimensional periodic pattern, a p-type contact layer 8, a ring-shaped p-side electrode 10 and a p-side drawing electrode 11, which are sequentially formed on the substrate; and an n-side electrode 12 formed on the bottom surface of the GaAs substrate 1.

In the surface emitting laser, due to the two-dimensional arrangement of circular holes (air holes) in a lamination plane (i.e., a plane parallel to the principal plane of the substrate), a refractive index is slightly reduced, whereby a two-dimensional periodic distribution of the refractive index in the lamination plane is obtained. With the configuration, a point defect region in the center portion where no hole is present acts as a core while the region around the center portion where the two-dimensional circular hole arrangement is formed acts as a clad. Because of a transverse mode control mechanism based on such a refractive index light confinement, an area of the active region in which only the fundamental transverse mode can oscillate can be enlarged. Such a surface emitting laser is called a photonic crystal surface emitting laser, and has been attracting an attention because of its possibility of high output and low resistance characteristics.

However, in the conventional photonic crystal surface emitting laser shown in FIG. 11, in order to achieve the refractive index confinement required for transverse mode control, it is necessary to etch the upper multilayer film reflecting mirror to a depth of not less than 3 μm, which corresponds to an entire thickness of the upper multilayer film reflecting mirror ordinarily having 30 pairs of multilayer film, when forming the two-dimensional circular hole arrangement. Accordingly, it is difficult to control the depth of the circular holes, resulting in lowering of product yield of single transverse mode.

Further, such deep holes are likely to scatter the light. Accordingly, it is likely that optical loss increases, a threshold current increases, and optical output decreases. In addition, because the circular holes are arranged on a current injection path, a device resistance increases.

### SUMMARY OF THE INVENTION

It is an object of the present invention to at least partially solve the problems in the conventional technology.

According to a first aspect of the present invention, a surface emitting semiconductor laser comprises a semiconductor substrate; a lamination structure including at least a lower multilayer film reflecting mirror, an active layer, and an upper multilayer film reflecting mirror formed on the semiconductor substrate; and an upper electrode and a lower electrode for supplying an electric power to the active layer.

The upper multilayer film reflecting mirror has a refractive index having a two-dimensional periodic distribution within a lamination plane except a predetermined region in the lamination plane. A circular hole layer having at least one layer is formed above the active layer. The circular hole layer includes a plurality of circular holes arranged in a peripheral region surrounding the predetermined region in a two-dimensional periodic pattern, so that a multilayer film formed on the circular hole layer including an inside of the circular holes to constitute the upper multilayer film reflecting mirror forms the two-dimensional periodic distribution of the refractive index together with the circular hole layer.

According to a second aspect of the present invention, a method of manufacturing a surface emitting laser comprises the steps of forming sequentially an lower multilayer film reflecting mirror and an active layer on a semiconductor substrate; forming a circular hole layer having at least one layer on the active layer, said circular hole layer including a plurality of circular holes arranged in a peripheral region surrounding a predetermined region within a lamination plane in a two-dimensional periodic pattern; forming sequentially a multilayer film on the circular hole layer including an inside of the circular holes to form an upper multilayer film reflecting mirror so that the upper multilayer film reflecting mirror has a refractive index having a two-dimensional periodic distribution over a lamination plane except an upper portion of the predetermined region; and forming an upper electrode and a lower electrode for supplying an electric power to the active layer.

The above and other objects, features, advantages and technical and industrial significance of this invention will be better understood by the following detailed description of preferred embodiments of the invention with reference to the accompanying drawings.

### BRIEF DESCRIPTION OF THE DRAWINGS

FIG. 1 is a schematic cross sectional view showing a surface emitting laser according to a first embodiment of the present invention;

FIG. 2 is a plan view of a mesa post of the surface emitting laser shown in FIG. 1;

FIG. 3 is a schematic cross sectional view No. 1 showing a method of manufacturing the surface emitting laser shown in FIG. 1;

FIG. 4 is a schematic cross sectional view No. 2 showing the method of manufacturing the surface emitting laser shown in FIG. 1;

FIG. 5 is a schematic cross sectional view No. 3 showing the method of manufacturing the surface emitting laser shown in FIG. 1;

FIG. 6 is a schematic cross sectional view No. 4 showing the method of manufacturing the surface emitting laser shown in FIG. 1;

FIG. 7 is a schematic cross sectional view No. 5 showing the method of manufacturing the surface emitting laser shown in FIG. 1;

FIG. 8 is a schematic cross sectional view No. 6 showing the method of manufacturing the surface emitting laser shown in FIG. 1;

FIG. 9 is a schematic cross sectional view showing a surface emitting laser according to a second embodiment of the present invention;

FIG. 10 is a schematic cross sectional view showing a surface emitting laser according to a third embodiment of the present invention; and

FIG. 11 is a schematic cross sectional view showing a conventional surface emitting laser.

### DETAILED DESCRIPTION OF THE PREFERRED EMBODIMENTS

### First Embodiment

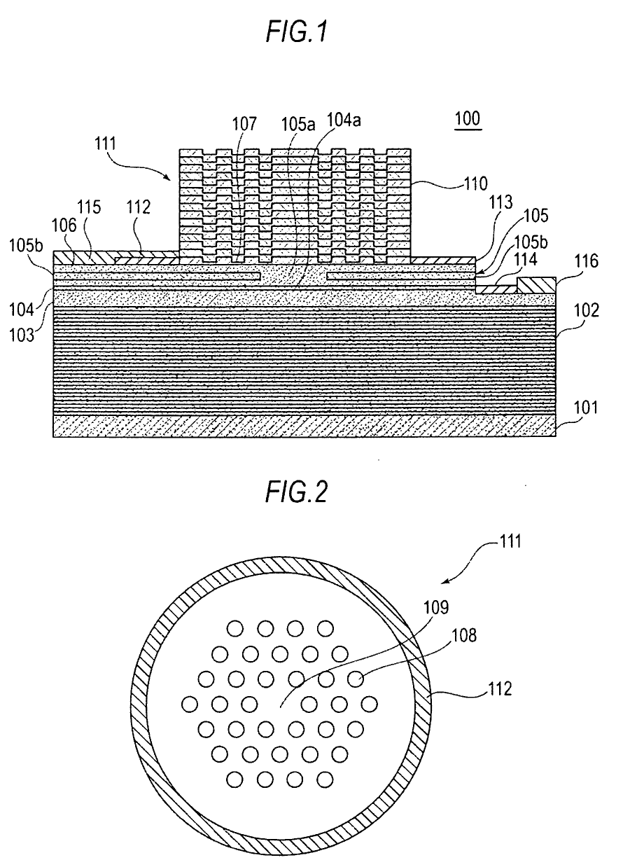

A first embodiment of the present invention is explained below with reference to the drawings. FIG. 1 is a cross sectional view schematically showing a surface emitting laser according to the first embodiment of the present invention, and FIG. 2 is a plan view of a mesa post of the surface emitting laser shown in FIG. 1.

In the present embodiment, the surface emitting laser 100 is designed to have an oscillation wavelength of 1300 nm. The surface emitting laser 100 includes: a semi-insulating GaAs substrate 101, for example; a lamination structure having a lower reflecting mirror 102, an n-type contact layer 103, an active layer 104 having a quantum well structure, a current constriction layer 105 having a current aperture 105a and a current blocking region 105b, a p-type contact layer 106, and an upper multilayer film reflecting mirror 110 having a lowermost layer 107 as a starting point of a two-dimensional periodic arrangement, which are sequentially formed in this order on the GaAs substrate 101; and a p-side electrode 112 and an n-side electrode 114 formed on the p-type contact layer 106 and the n-type contact layer 103, respectively.

In the present embodiment, a two-dimensional distribution of a refractive index is formed in a peripheral region of the upper multilayer film reflecting mirror 110, and an outer region of the peripheral region is removed by etching to form a first mesa post with a column shape. Further, an outer region of a lamination structure including the active layer 104 formed on the n-type contact layer 103, the current constriction layer 105 and the p-type contact layer 106 are removed by etching or the like to form a second mesa post 113 with a column shape.

In the present embodiment, in the lowermost layer 107 of the upper multilayer film reflecting mirror 110, a two dimensional periodic arrangement of circular holes 108 is formed in such a manner that a plurality of circular holes 108 are arranged in an equilateral triangular lattice pattern over a lamination plane, as shown in FIG. 2. The circular holes 108 may penetrate the lowermost layer 107, or may be formed to have a bottom in the lowermost layer 107. Layers of the upper multilayer film reflecting mirror 110 are formed sequentially on the lowermost layer 107 to the topmost layer, at least partially keeping the shape of the two-dimensional circular hole arrangement formed in the lowermost layer 107.

In the present embodiment, the two-dimensional circular hole arrangement has a point defect 109 in a center thereof, where no circular hole is present. Based on such a circular hole arrangement, an average refractive index of the portion where the circular holes are formed is slightly smaller than an average refractive index of the point defect 109 where no circular hole is present. Accordingly, the peripheral region where the circular holes are formed acts as a clad for light propagating in the point defect 109. That is, the point defect 109 acts as a core and a light emitting part to obtain a fundamental transverse mode oscillation. In FIG. 2, the point defect 109 is formed as a region where one of the circular holes is not formed. The point defect 109 may be formed as a region where more than two holes are not formed.

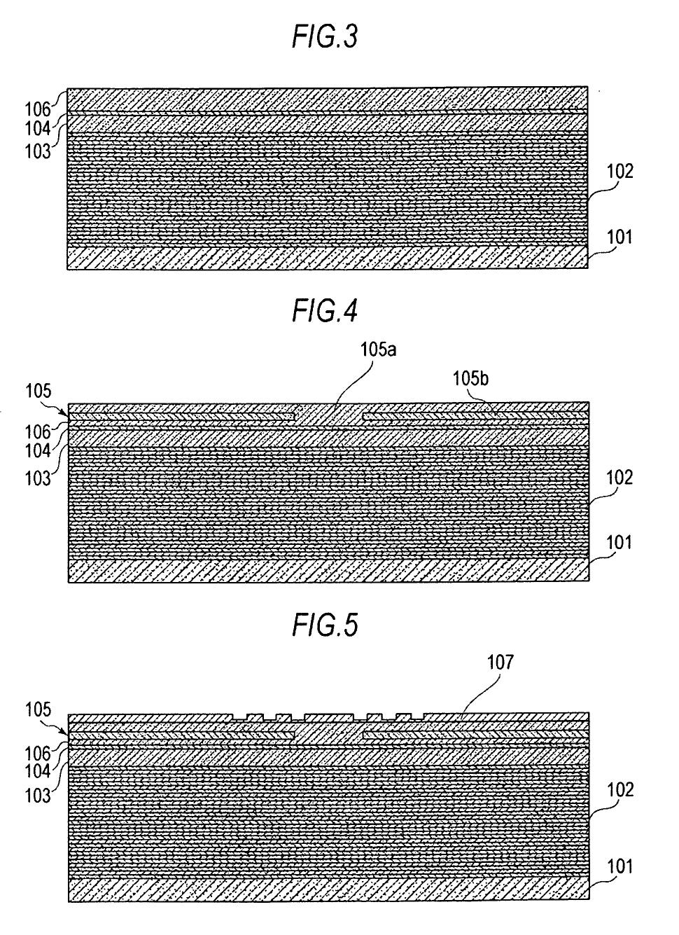

The surface emitting laser 100 of the above-described embodiment can be manufactured by a following manufacturing process, for example. First, a lower DBR mirror 102 constituted by a semiconductor multilayer film is formed by depositing plural pairs of composite semiconductor layers of GaAs/AlAs pair layer, for example, each layer having a thickness of λ/4n, where λ is an oscillation wavelength and n is a refractive index, on a semi-insulating GaAs substrate 101 using MOCVD or MBE method. Then, an n-type contact layer 103 of n-GaAs, for example, an active layer 104 having a multiple quantum well (MQW) structure in which three pairs of composite semiconductor layers of GaInNAs/GaAs, for example, are laminated, and a p-type contact layer 106 of p-GaAs, for example, are sequentially formed on the lower DBR mirror 102 (see FIG. 3).

Thereafter, a circular photoresist pattern having a predetermined size is formed on the lamination structure of FIG. 3, using lithography technique using photoresist. Hydrogen ions are implanted into a peripheral region of the lamination structure using the circular photoresist pattern as a mask, whereby a current constriction layer 105 having a current blocking region 105b in the peripheral region and a current aperture 105a in the central region is formed in the p-type contact layer 106 (see FIG. 4). The mask may be formed of Au (gold) or the like, instead of the photoresist.

In addition, implanted ions are not restricted to hydrogen, but may be other ions such as oxygen, as long as they are capable of forming an insulating layer with sufficiently high resistance. With the current constriction layer 105, a current injected from the p-side electrode 112 is constricted and concentrated in the central current aperture 105a, thereby increasing a current density in the current aperture 105a.

Then, a SiNₓ film is formed on a surface of the lamination structure using plasma CVD method. The SiNₓ film is etched by an ordinary lithography technique using a photoresist and RIE (reactive ion etching) using a fluorine-based gas, whereby a circular hole layer 107 with a two-dimensional circular hole arrangement shown in FIG. 2 is formed (see FIG. 5). The two-dimensional circular hole arrangement has a point defect 109 in a center thereof, where no circular hole is present, and is formed in a triangular lattice pattern of a two-dimensional arrangement period of 5 μm, with a diameter of each hole of 3 μm.

In the present embodiment, an etching depth of the circular holes is, for example, 50 nm, which is smaller than a thickness of a circular hole layer 107. The arrangement period, the diameter, the depth or the like of the circular holes 108 are suitably selected such that a fundamental transverse mode oscillation is obtained in the lamination plane based on a difference in the average refractive index between the portion where the circular holes are formed and the point defect 109 where no circular hole is present.

In the present embodiment, the etching depth of the two-dimensional circular hole arrangement is as small as 50 nm. Further, the etching is done for one layer of the dielectric multilayer film. Accordingly, it is possible to precisely control the etching depth as compared with the conventional art in which the circular holes are deeply formed in the most part of the thickness of the semiconductor multilayer film reflecting mirror. Further, in the present embodiment, light is unlikely to be lost by scattering by the circular holes.

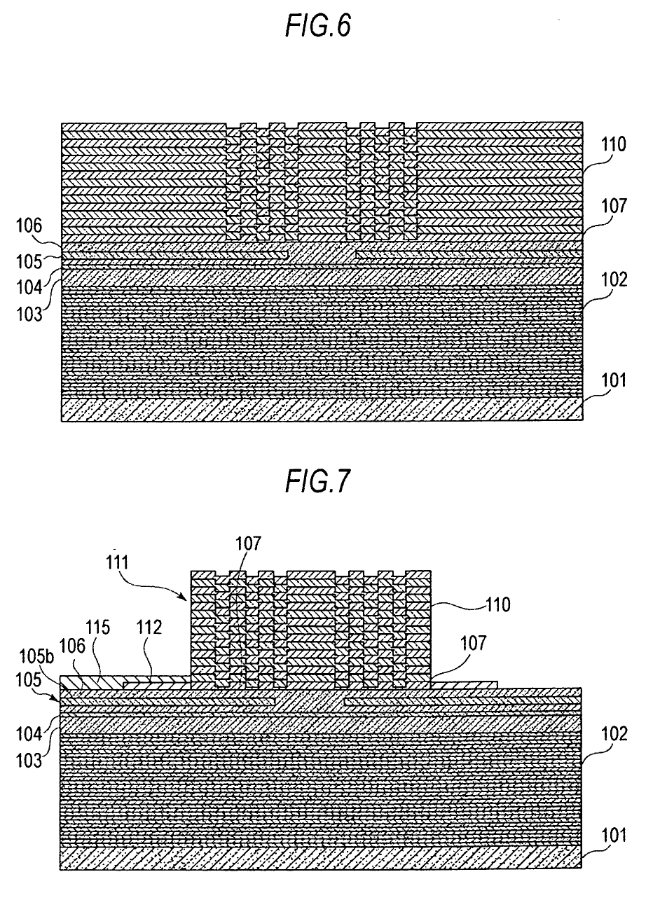

Thereafter, an upper DBR mirror 110 constituted by a dielectric multilayer film is formed by depositing twelve pairs of dielectric layers of, for example, SiO₂/SiNₓ pair layers, using plasma CVD method, on the lowermost layer 107 of the upper multilayer film reflecting mirror 110, in which the circular holes 108 are formed (see FIG. 6). In this step, the two-dimensional circular hole arrangement formed in the lowermost layer 107 of SiNₓ film is transferred to upper layers, starting from the lowermost layer 107 and at least partially keeping the shape of the circular hole arrangement. Thus, the two-dimensional distribution of the refractive index is formed within the entire of the lamination of the upper DBR mirror 110.

The upper DBR mirror 110 of dielectric multilayer film constituted by SiO₂/SiNₓ pair layers has a light transmission property of predetermined transmittance as a whole. In the surface emitting laser 100, the dielectric multilayer film is used for the upper multilayer film reflecting mirror. Accordingly, a light absorption loss in the upper DBR mirror 110 is significantly reduced as compared with the case where a semiconductor multilayer film is used for the upper multilayer film reflecting mirror.

Further, in the present embodiment, the thickness of the p-type contact layer 106 and the thickness of the lowermost layer of the upper multilayer film reflecting mirror 110, in which the circular holes are formed, are suitably selected such that a node of the standing wave of the light intensity is located within the p-type contact layer 106, which has a high carrier concentration and therefore has a large absorption loss. In this case, a peak of the standing wave of the light intensity is located within the lowermost layer 107 of the upper multilayer film reflecting mirror 110.

Therefore, a coupling efficiency between the two-dimensional distribution of the refractive index and the light can be enhanced and it is possible to effectively control the transverse mode with the two-dimensional distribution of the refractive index. Note that the circular hole layer, which is to be a starting point of the two-dimensional distribution of the refractive index, is not necessarily restricted to the lowermost layer 107 of the upper multilayer film reflecting mirror. Further, the circular hole layer is not restricted to a single layer, but may be a lamination of about six pairs of layers.

Then, a peripheral region of the above-described upper DBR mirror 110 is etched to a depth reaching the p-type contact layer 106, to leave the remaining internal central region as a mesa post 111. Thereafter, a photoresist pattern having a ring-shaped aperture is formed on the surrounding region of the mesa post, by lithography technique using photoresist. AuZn, for example, is deposited inside the aperture of the photoresist pattern, to form a ring-shaped p-side electrode 112 (see FIG. 7). Further, a p-side drawing electrode 115 of Ti/Au is formed. As shown in FIG. 7, the p-side electrode 112 and the p-side drawing electrode 115 are formed in a ring shape on the p-type contact layer 106 so as to surround a part of the upper multilayer film reflecting mirror 110 above the current injection region 104a.

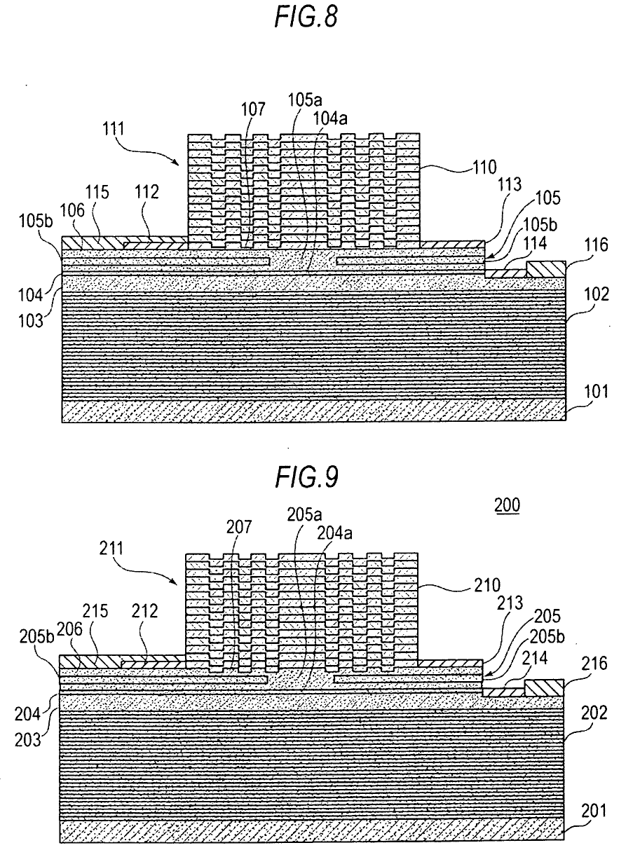

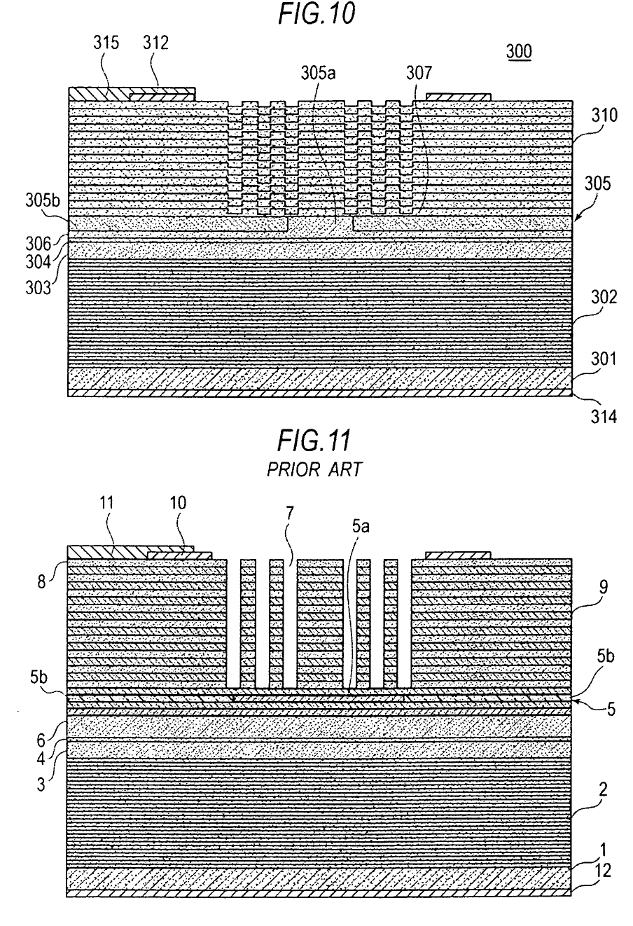

Thereafter, a portion of the above-mentioned lamination structure outer than the mesa post 111 and the p-side electrode 112 is etched to a depth reaching the n-type contact layer 103, to form a mesa post 113. Then, a predetermined aperture is formed in the photoresist by lithography technique using photoresist, and AuGeNi is deposited inside the aperture to form an n-side electrode 114 having a predetermined shape (see FIG. 8). Further, an n-side drawing electrode 116 of Ti/Au is formed. Thus, the n-side electrode 114 and the n-side drawing electrode 116 are formed on the n-type contact layer 103 so as to surround a bottom of the mesa post 113.

Then, a back face of the semi-insulating GaAs substrate 101 is polished, until the substrate thickness is about 200 μm. In this way, the surface emitting laser of the present embodiment is obtained.

As described above, in the surface emitting laser 100 according to the present embodiment, the p-side electrode 112 and the n-side electrode 114, including respectively the drawing electrode 115 and the drawing electrode 116, are formed on the contact layers 106, 103, to form a intra-cavity electrode structure. In this structure, the two dimensional circular hole arrangement is not present on the current path from the p-type contact layer 106 to the current aperture 105a of the current constriction layer. Accordingly, it is possible to prevent an excessive increase of device resistance as compared with the conventional surface emitting laser.

### Second Embodiment

A surface emitting laser according to a second embodiment of the present invention is explained below with reference to FIG. 9. The surface emitting laser 200 according to the second embodiment is designed to have an oscillation wavelength of 1100 nm. The surface emitting laser 200 includes a semi-insulating GaAs substrate 201 and a lamination structure having a lower reflecting mirror 202, an n-type contact layer 203, an active layer 204, a current constriction layer 205, a p-type contact layer 206, and an upper multilayer film reflecting mirror 210, which are sequentially laminated on the GaAs substrate 201.

A plurality of circular holes are formed on an upper region of the p-type contact layer 206, and the upper region of the p-type contact layer 206 is to be a starting point of the two-dimensional distribution of the refractive index. An n-side electrode 214 is formed on the n-type contact layer 203, and a p-side electrode 212 is formed on the p-type contact layer 206. An outer region of the upper multilayer film reflecting mirror 210 is removed to form a first mesa post 211 with a column shape. Further, a portion of the active layer 204, the current constriction layer 205 and the p-type contact layer 206 outer than the p-side electrode 212 is removed to form a second mesa post 213 with a column shape.

In the present embodiment, a two-dimensional periodic distribution of the refractive index is formed within the upper multilayer film reflecting mirror 210 above the upper region 207 of the p-type contact layer 206. The two-dimensional periodic distribution of the refractive index starts from the upper region 207 of the p-type contact layer 206, in which a two-dimensional periodic distribution of circular holes are formed. The circular holes formed in the upper region 207 are distributed as shown in FIG. 2. That is, the plurality of circular holes are arranged in a two-dimensional equilateral triangular lattice pattern over the lamination plane. The upper multilayer film reflecting mirror 210 is laminated on the p-type contact layer 206, at least partially keeping the shape of the two-dimensional circular hole arrangement formed in the p-type contact layer 206.

As shown in FIG. 2, the circular hole arrangement has a point defect 109 in a center thereof, where no hole is present. Based on such a circular hole arrangement, an average refractive index of the upper region 207 of the p-type contact layer 206 where the holes are formed and a portion of the upper multilayer film reflecting mirror 210 above the upper region 207 is slightly smaller than an average refractive index of the point defect 109 where no holes is present and a portion of the upper multilayer film reflecting mirror 210 above the point defect 109. Accordingly, the portion where the circular holes are formed and its upper region act as a clad for light propagating in the point defect 109. That is, the point defect 109 constitutes a light emitting part to obtain a fundamental transverse mode oscillation. The point defect 109 is not restricted to a point defect where one circular hole is omitted, as shown in FIG. 2, but may be a point defect where a plurality of circular holes are omitted.

The surface emitting laser according to the present embodiment can be manufactured by a following manufacturing process, for example. First, a lower multilayer film reflecting mirror (a lower DBR mirror) 202 constituted by a semiconductor multilayer film is formed by alternately depositing plural pairs of composite semiconductor layers of GaAs/AlAs, for example, on a semi-insulating GaAs substrate 201 using MOCVD or MBE method. Each layer of the semiconductor multilayer film reflecting mirror 202 has a thickness of λ/4n, where λ is the oscillation wavelength and n is the refractive index. Then, an n-type contact layer 203 of n-GaAs, for example, an active layer 204 having a multiple quantum well (MQW) structure in which three pairs of composite semiconductor layers of GaInAs/GaAs, for example, are laminated, and a p-type contact layer 206 of p-GaAs, for example, are sequentially formed on the lower multilayer film reflecting mirror 202.

Thereafter, a circular photoresist pattern having a predetermined size is formed on the lamination structure by lithography technique using photoresist. Hydrogen ions are implanted into a peripheral region of the lamination structure using the circular photoresist pattern as a mask, whereby a current constriction layer 205 having a current blocking region 205b and a current aperture 205a is formed in the p-type contact layer 206. The ion implanting mask may be Au (gold) or the like, instead of the photoresist. In addition, the implanted ions are not restricted to hydrogen, and may be other ions such as oxygen, as long as they are capable of forming an insulating layer with sufficiently high resistance. With the current constriction layer 205, a current injected from the p-side electrode 212 is constricted and concentrated in the current aperture 205a, thereby increasing a current density in the current aperture 205a.

Then, a SiNₓ film is formed on the lamination structure using plasma CVD method. The SiNₓ film is etched by an ordinary lithography technique using a photoresist and RIE (reactive ion etching) using a fluorine-based gas, whereby a two-dimensional circular hole arrangement is formed. The two-dimensional circular hole arrangement has a point defect in a center thereof, where no hole is present, and is formed in a triangular lattice pattern of an arrangement period of 5 μm, with a diameter of each hole of 3 μm.

In the present embodiment, an upper portion of the p-type contact layer 206 is etched by ICP-RIE (Inductively coupled plasma reactive ion etching) using chlorine gas, using the SiNₓ film having the two-dimensional circular hole arrangement as a mask. An etching depth is, for example, 50 nm. The arrangement period, the diameter, the depth or the like of the circular holes 108 are suitably selected such that a fundamental transverse mode oscillation is obtained in the lamination plane based on a difference in the average refractive index between the portion where the circular holes are formed and the point defect 109 where no hole is present.

In the present embodiment, the etching depth of the two-dimensional hole arrangement is as small as 50 nm. Further, the etching is done for only the upper portion of the p-type contact layer 206 formed of GaAs. Accordingly, it is possible to precisely control the etching process as compared with the conventional art in which the circular holes are deeply formed in the most part of the thickness of the semiconductor multilayer film reflecting mirror. Further, in the present embodiment, light is unlikely to be lost by scattering by the circular holes.

Thereafter, an upper DBR mirror 210 constituted by a dielectric multilayer film is formed by depositing twelve pairs of composite dielectric layer of, for example, SiO₂/SiNₓ pair layer, using plasma CVD method. In this step, the two-dimensional circular hole arrangement forms the two-dimensional periodic distribution of the refractive index within the upper DBR mirror 210, starting from the upper region 207 of the p-type contact layer 206 and keeping at least partially the shape of the circular hole arrangement.

The dielectric multilayer film reflecting mirror 210 constituted by SiO₂/SiNₓ has a light transmission property of predetermined transmittance as a whole. In the surface emitting laser 200, the dielectric multilayer film is used for the upper multilayer film reflecting mirror 210. Accordingly, a light absorption loss in the upper DBR mirror 210 is significantly reduced as compared with the case where a semiconductor multilayer film is used for the upper multilayer film reflecting mirror.

A peak of the standing wave of the light intensity is located at the upper region 207 of the p-type contact layer 206, which is to be a starting point of the two-dimensional distribution of the refractive index. In this configuration, a coupling efficiency between the two-dimensional circular hole arrangement and the light can be enhanced, and it is possible to effectively control the transverse mode with the two-dimensional circular hole arrangement.

Then, a peripheral region of the above-described upper DBR mirror 210 is etched to a depth reaching to the p-type contact layer 206, to leave the remaining internal central region as a mesa post (a first mesa post) 211. Thereafter, a photoresist pattern having a ring-shaped aperture is formed on the surrounding region of the first mesa post 211, by lithography technique using photoresist. AnZn, for example, is deposited inside the aperture of the photoresist pattern to form a ring-shaped p-side electrode 212 around the mesa post 211. Further, a p-side drawing electrode 215 of Ti/Au is formed. Thus, the p-side electrode 212 is formed in a ring-shape on the p-side contact layer 206 so as to surround a part of the upper multilayer film reflecting mirror 210 above the current injection region 204a.

In the present embodiment, the two-dimensional circular hole arrangement is formed shallowly only on an upper portion of the p-type contact layer 206, on a current injection path from the p-type contact layer 206 to the current aperture 205a of the current constriction layer. Accordingly, it is possible to prevent an excessive increase of device resistance as compared with the conventional photonic crystal surface emitting laser.

Thereafter, a portion of the lamination structure outer than the mesa post 211 and the p-side electrode 212 is etched to a depth reaching the n-type contact layer 203 to form a mesa post (a second mesa post) 213. Then, a predetermined aperture is formed in the photoresist by lithography technique using photoresist, and AuGeNi is deposited to form an n-side electrode 214 having a predetermined shape in the aperture. Further, an n-side drawing electrode 216 of Ti/Au is formed. Thus, the n-side electrode is formed on the n-type contact layer 203 so as to surround a bottom of the mesa post 213. The p-side electrode 212 and the n-side electrode 214 are connected to the p-side drawing electrode 215 and the n-side drawing electrode 216, respectively. Then, a back face of the semi-insulating GaAs substrate 201 is polished, until the substrate thickness is about 200 μm. In this way, the surface emitting laser of the present embodiment is obtained.

### Third Embodiment

A surface emitting laser according to a third embodiment of the present invention is explained below with reference to FIG. 10. The surface emitting laser 300 is designed to have an oscillation wavelength of 850 nm. The surface emitting laser 300 includes a n-type GaAs substrate 301 and a lamination structure having a lower multilayer film reflecting mirror 302, an n-type clad layer 303, an active layer 304, a current constriction layer 305, a p-type clad layer 306, and an upper multilayer film reflecting mirror 310, which are sequentially laminated in this order on the GaAs substrate 301. The upper multilayer film reflecting mirror 310 includes a lowermost layer 307 which is to be a starting point of a two-dimensional periodic distribution of the refractive index. An n-side electrode 314 is formed on a back face of the GaAs substrate 301 and a p-side electrode 312 is formed on the upper multilayer film reflecting mirror 310.

In the present embodiment, in the lowermost layer 307 of the upper multilayer film reflecting mirror 310, a plurality of circular holes 108 are two-dimensionally arranged in an equilateral triangular lattice pattern over a lamination plane, as shown in FIG. 2. The two-dimensional circular hole arrangement forms a two-dimensional distribution of the refractive index within the upper multilayer film reflecting mirror 310, keeping at least partially the shape of the two-dimensional circular hole arrangement. The circular hole arrangement in the lowermost layer 307 has a point defect 109 in a center thereof, where no hole is present, as shown in FIG. 2.

Based on such a circular hole arrangement, an average refractive index of the portion of the lowermost layer 307 and the portion of the upper DBR mirror 310 formed on the lowermost layer 307, where the circular holes are formed, is slightly smaller than an average refractive index of the point defect 109 and the portion of the upper DBR mirror 310 formed on the point defect 109, where no circular hole is present. Accordingly, the region including the portion where the circular holes are formed acts as a clad for light propagating in the point defect 109. The point defect 109 acts as a light emitting part to obtain a fundamental transverse mode oscillation. The point defect is not restricted to a point defect where one hole is omitted, but may be a point defect where a plurality of holes are omitted.

The surface emitting laser 300 according to the present embodiment can be manufactured by a following manufacturing process. First, a lower DBR mirror 302 constituted by a semiconductor multilayer film is formed by depositing plural pairs of composite semiconductor layers of GaAs/AlAs pair layer, for example, using MOCVD or MBE method. Each layer of the lower DBR mirror 302 has a thickness of λ/4n, where λ is the oscillation wavelength and n is the refractive index.

Then, an n-type clad layer 303 of n-AlGaAs, for example, an active layer 304 having a multiple quantum well (MQW) structure in which three pairs of composite semiconductor layers of GaAs/AlGaAs, for example, are laminated, a p-type clad layer 306 of p-AlGaAs, for example, and a lowermost pair layer of AlGaAs/GaAs pair layer 307 of the upper DBR mirror, are sequentially formed in this order on the lower DBR mirror 302.

Thereafter, a current constriction layer 305 having a current blocking region 305b in its peripheral portion and a current aperture 305a of a predetermined size in its central portion is formed in the p-type clad layer 306, using ion implanting method or the like. The method to form the current constriction structure is not restricted to the ion implanting method, and a selective oxidation method of AlAs or the like may be used instead. With the current constriction layer 305, a current injected from the p-side electrode 312 is constricted and concentrated in the current aperture 305a, thereby increasing a current density in the current aperture 305a.

Then, a SiNₓ film is formed on the lamination structure using plasma CVD method. The SiNₓ film is etched by an ordinary lithography technique using a photoresist and RIE (reactive ion etching) using a fluorine-based gas, whereby a two dimensional circular hole arrangement is formed. The two dimensional circular hole arrangement has a point defect in its center, where no hole is present, and is formed in a triangular lattice pattern of an arrangement period of 4 μm, with a diameter of each hole of 2.5 μm.

In the present embodiment, a part of the lowermost GaAs layer 307 of the upper DBR mirror 310 is etched by ICP-RIE (inductively coupled plasma reactive ion etching) using chlorine gas, using the SiNₓ film having the two-dimensional circular hole arrangement as a mask. An etching depth of the circular holes is 40 nm, for example. The arrangement period, the diameter, the depth or the like of the circular holes 108 are suitably selected such that a fundamental transverse mode oscillation is obtained in the lamination plane based on a difference of average reflective index between the portion where the circular holes are formed and the point defect 109 where no hole is present.

In the present embodiment, the etching depth of the two-dimensional circular hole arrangement is as small as 40 nm. Further, the etching is done for only the GaAs layer 307. Accordingly, it is possible to precisely control the etching process as compared with the conventional art in which the circular holes are deeply formed in the most part of the thickness of the semiconductor multilayer film reflecting mirror. Further, in the present embodiment, light is unlikely to be lost by scattering by the circular holes.

Thereafter, an upper DBR mirror 310 constituted by a semiconductor multilayer film is formed by depositing twenty-five pairs of composite semiconductor layer of, for example, GaAs/AlGaAs pair layer, using MOCVD or MBE method. In this step, the two-dimensional circular hole arrangement forms the two-dimensional periodic distribution of the refractive index within the upper DBR mirror 310, starting from the lowermost layer 307 of the upper DBR mirror 310 and keeping at least partially the shape of the circular hole arrangement.

In the present embodiment, the two-dimensional circular hole arrangement is formed in the lowermost layer 307 of the upper DBR mirror 310. However, the layer in which the two-dimensional circular hole arrangement is formed is not restricted to the lowermost layer 307. Preferably, the two-dimensional circular hole arrangement is formed in the layer in which the oscillation laser light is sufficiently intense. For example, it is preferable that the two-dimensional circular hole arrangement is formed within three pairs from the lowermost layer.

Then, a photoresist pattern having a ring-shaped aperture is formed on the lamination structure using lithography technique using photoresist. AuZn, for example, is deposited to form a ring-shaped p-side electrode 312 in the aperture. Further, a p-side drawing electrode 315 of Ti/Au is formed. In the surface emitting laser according to the present embodiment, no circular hole is present on a current injection path from the p-side electrode 312 to the current aperture 305a of the current constriction layer 305. Accordingly, it is possible to prevent an excessive increase of device resistance as compared with the conventional surface emitting laser.

Thereafter, a back face of the n-type GaAs substrate 301 is polished, until the substrate thickness is about 200 μm. Ti/Au is deposited onto the polished back face to form an n-side electrode 314. In this way, the surface emitting laser of the present embodiment is obtained.

In the present embodiment, the n-type substrate is used, and the semiconductor multilayer film is used for the upper multilayer film reflecting mirror. Accordingly, the upper electrode and the lower electrode are formed outside the laser cavity.

As described above, in the surface emitting laser according to the present invention, the two-dimensional circular hole arrangement is formed in the circular hole layer inside the cavity, and the two-dimensional periodic distribution of the refractive index is formed over the lamination plane of the upper multilayer film reflecting mirror, starting from the circular hole layer. Under this configuration, the depth of the two-dimensionally periodically arranged circular holes, which gives the two-dimensional distribution of the refractive index sufficient for transverse mode control, can be small. Accordingly, it is possible to easily control the process, and single transverse mode oscillation is effectively achieved. Further, it is possible to reduce a scattering loss of light as compared with the conventional art.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A surface emitting semiconductor laser comprising:
a semiconductor substrate;
a lamination structure including at least a lower multilayer film reflecting mirror, an active layer, and an upper multilayer film reflecting mirror formed on the semiconductor substrate; and
an upper electrode and a lower electrode for supplying an electric power to the active layer,
wherein said upper multilayer film reflecting mirror has a refractive index having a two-dimensional periodic distribution within a lamination plane except a predetermined region in the lamination plane, and
a circular hole layer having at least one layer is formed above the active layer, said circular hole layer including a plurality of circular holes arranged in a peripheral region surrounding the predetermined region in a two-dimensional periodic pattern so that a multilayer film formed on the circular hole layer including an inside of the circular holes to constitute the upper multilayer film reflecting mirror forms the two-dimensional periodic distribution of the refractive index together with the circular hole layer.

2. The surface emitting semiconductor laser according to claim 1, wherein said circular hole layer includes a lowermost layer of the multilayer film constituting the upper multilayer film reflecting mirror.

3. The surface emitting semiconductor laser according to claim 1, wherein said lamination structure further includes a first contact layer formed between the upper multilayer film reflecting mirror and the active layer and contacting with the upper electrode, said circular hole layer including the first contact layer.

4. The surface emitting semiconductor laser according to claim 3, wherein said upper multilayer film reflecting mirror is formed of a dielectric multilayer film constituting a first mesa post with a column shape, said first mesa post being formed by removing a radially outer region of the peripheral region, said upper electrode contacting with the first contact layer in an radially outer region of the first mesa post.

5. The surface emitting semiconductor laser according to claim 4, wherein said lamination structure further includes a second contact layer formed between the lower multilayer film reflecting mirror and the active layer and contacting with the lower electrode, said first contact layer, said active layer, and said upper electrode forming a second mesa post with a column shape by removing a radially outer region of the upper electrode, said lower electrode contacting with the second contact layer in a radially outer region of the second mesa post.

6. The surface emitting semiconductor laser according to claim 1, wherein said upper multilayer film reflecting mirror is formed of a semiconductor multilayer film.

7. The surface emitting semiconductor laser according to claim 1, wherein said upper multilayer film reflecting mirror has the refractive index having the two-dimensional periodic distribution to generate a fundamental transverse mode laser oscillation in the lamination plane.

8. The surface emitting semiconductor laser according to claim 1, wherein said circular hole layer includes not more than six layers.

9. The surface emitting semiconductor laser according to claim 1, wherein said lamination structure further includes a current constriction layer formed in a neighboring portion of the active layer in the upper multilayer film reflecting mirror, or formed between the upper multilayer film reflecting mirror and the active layer.

10. The surface emitting semiconductor laser according to claim 1, wherein said circular hole layer is adopted to form an intensity peak of a standing wave of laser light therein.

11. A method of manufacturing a surface emitting laser comprising the steps of:
forming sequentially an lower multilayer film reflecting mirror and an active layer on a semiconductor substrate;
forming a circular hole layer having at least one layer on the active layer, said circular hole layer including a plurality of circular holes arranged in a peripheral region surrounding a predetermined region within a lamination plane in a two-dimensional periodic pattern;
forming sequentially a multilayer film on the circular hole layer including an inside of the circular holes to form an upper multilayer film reflecting mirror so that the upper multilayer film reflecting mirror has a refractive index having a two-dimensional periodic distribution over a lamination plane except an upper portion of the predetermined region; and
forming an upper electrode and a lower electrode for supplying an electric power to the active layer.

12. The method according to claim 11, wherein, in the step of forming the circular hole layer, said circular hole layer includes a lowermost layer of the upper multilayer film reflecting mirror.

13. The method according to claim 11, wherein, in the step of forming the multilayer film, said multilayer film includes a dielectric multilayer film, and in the step of forming the circular hole layer, said circular hole layer includes a contact layer between the upper multilayer film reflecting mirror and the active layer and contacting with the upper electrode.
